(19) United States
(12) Patent Application Publication
(10) Pub. No.: US 2008/0314743 A1
(43) Pub. Date: Dec. 25, 2008

(54) Shadow mask

(75) Inventors: Young Woo LEE, Gyeonggi-do (KR); Gee Lyong KIM, Gyeonggi-do (KR); Hang Kyu CHO, Gyeonggi-do (KR); Jeong Min CHO, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/081,428

(22) Filed: Apr. 16, 2008

(30) Foreign Application Priority Data
Jun. 20, 2007 (KR) 10-2007-0060585

(51) Int. Cl. C23C 14/00

(52) U.S. Cl. 204/298.11

(57) ABSTRACT

Provided is a shadow mask including a substrate; a mask that is formed to have an opening for transferring a thin film onto the substrate in a desired shape; and a delamination-preventing polymer layer formed on the mask.

### CROSS-REFERENCE TO RELATED APPLICATIONS

This application claims the benefit of Korean Patent Application No. 10-2007-0060585 filed with the Korea Intellectual Property Office on Jun. 20, 2007, the disclosure of which is incorporated herein by reference.

### BACKGROUND OF THE INVENTION

1. Field of the Invention

The present invention relates to a shadow mask which can prevent dust from occurring during a vacuum deposition or sputtering process.

2. Description of the Related Art

To form a metal layer in semiconductor elements or display elements, a thin film is deposited on the entire structure thereof through a chemical vapor deposition (CVD) method or the like, and a portion of the metal film is removed through a wet or dry etching process using a photosensitive film mask.

In a process of manufacturing semiconductor elements or display elements requiring a large area in which the photosensitive film mask cannot be used, a shadow mask is applied in such a manner that films and patterns can be simultaneously formed by manufacturing only a mask.

Referring to FIGS. 1, 2A, and 2B, a conventional shadow mask will be described.

FIG. 1 is a schematic view of a conventional shadow mask. The shadow mask 100 includes a substrate 110 and a mask 120 having an opening for transferring a thin film onto the substrate 110 in a desired shape. The mask 120 is formed of a metallic material.

Referring to FIGS. 2A and 2B, the conventional shadow mask will be described more specifically.

FIGS. 2A and 2B are conceptual cross-sectional views for explaining a method of forming a metal layer by using the conventional shadow mask.

First, as shown in FIG. 2A, a shadow mask 100 is prepared to perform vacuum deposition using an evaporator. The shadow mask 100 includes a substrate 110 and a mask 120 having an opening for transferring a thin film onto the substrate 110 in a desired shape.

Then, as shown in FIG. 2B, a thin film 130 is formed on the substrate 110 on which the mask 120 is disposed, that is, on the shadow mask 100 through the vacuum deposition. The thin film 130 is formed of metal such as nickel or the like.

To deposit the thin film 130 through the vacuum deposition, metal should be heated at a high temperature of more than 700° C. so as to be evaporated.

Meanwhile, when the thin film 130 is changed from a gas phase to a solid phase, the thin film 130 loses heat energy and then contracts. However, since the mask 120 of the shadow mask 100 positioned under the thin film 130 has a different thermal expansion coefficient or contraction efficiency from the thin film 130, stress is accumulated at the interface between the mask 120 and the thin film 130.

However, as the thickness of the thin film 130 laminated on the shadow mask 100 increases, stress increases. Accordingly, when the stress becomes larger than an adhesive force, the thin film 130 is separated from the shadow mask 100 such that dust occurs, as indicated by a portion A of FIG. 3. FIG. 3 is a photograph for explaining the problem occurring when the conventional shadow mask is used, showing a state where the thin film is separated.

The dust degrades the quality of the thin film or causes an unexpected defect, thereby degrading the reliability of elements.

### SUMMARY OF THE INVENTION

An advantage of the present invention is that it provides a shadow mask in which a polymer layer is formed on a mask composed of metal such that a thin film formed on the mask is prevented from being separated.

Additional aspects and advantages of the present general inventive concept will be set forth in part in the description which follows and, in part, will be obvious from the description, or may be learned by practice of the general inventive concept.

According to an aspect of the invention, a shadow mask comprises a substrate; a mask that is formed to have an opening for transferring a thin film onto the substrate in a desired shape; and a delamination-preventing polymer layer formed on the mask.

Preferably, the mask is formed of metal.

Preferably, the polymer layer is composed of any one of noncrystalline PET (polyethylene terephthalate), plasticized PVC (polyvinyl chloride), high-density PE (polyethylene), PP (polypropylene), and PEI (poly-ether imide), which has a glass transition temperature of 40 to 250° C.

Preferably, the shadow mask further comprises a surface energy adjustment layer formed at the interface between the mask and the polymer layer.

Preferably, the surface energy adjustment layer is composed of an organic material having a molecular weight of 5000 to 10000 g/mol and a glass transition temperature of −100 to 100° C. The surface energy adjustment layer may be composed of any one selected from the group consisting of polyacrylate, polyurethane, and epoxy-based oligomer.

Preferably, silicon and fluorine compound are added to the surface energy adjustment layer. The added amount of the silicon and fluorine compound is set in the range of 1 to 20wt %.

Preferably, the surface energy adjustment layer is composed of a single layer or two or more layers.

Preferably, the shadow mask further comprises an adhesive layer formed at the interface between the polymer layer and the surface energy adjustment layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic view of a conventional shadow mask;

FIGS. 2A and 2B are conceptual cross-sectional views for explaining a method of forming a metal layer by using the conventional shadow mask;

FIG. 3 is a photograph for explaining the problem occurring when the conventional shadow mask is used;

FIG. 4 is a schematic view of a shadow mask according to a first embodiment of the invention;

FIG. 5 is a schematic view of a shadow mask according to the second embodiment of the invention; and

FIG. 6 is a schematic view of a shadow mask according to a modification of the second embodiment of the invention.

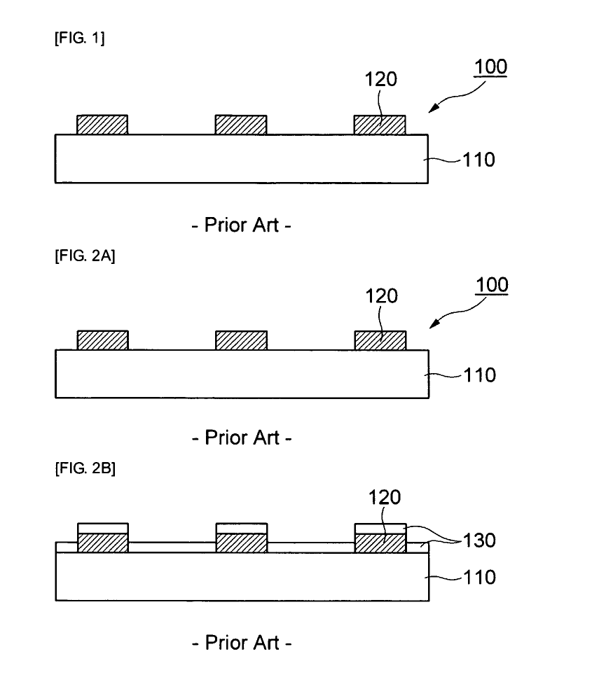

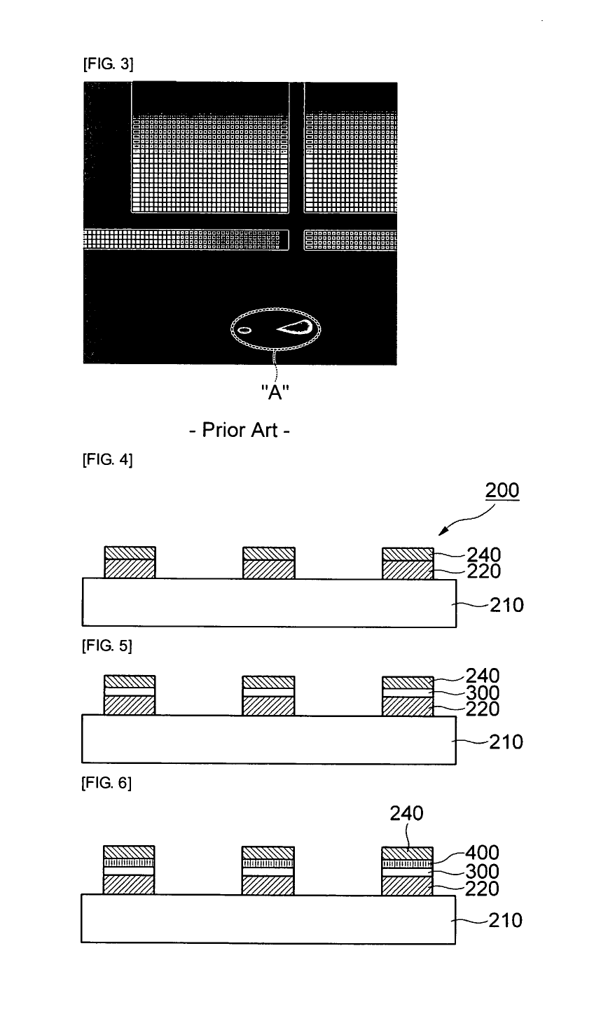

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a shadow mask according to the present invention will be described in detail with reference to the accompanying drawings.

### First Embodiment

FIG. 4 is a schematic view of a shadow mask according to a first embodiment of the invention.

As shown in FIG. 4, the shadow mask 200 according to the first embodiment of the invention includes a substrate 210, a mask 220 which is formed to have an opening for transferring a thin film onto the substrate 210 in a desired shape, and a delamination-preventing polymer layer 240 which is formed on the mask 220.

Preferably, the mask 220 is formed of metal.

When the delamination-preventing polymer layer 240 has a glass transition temperature of less than 40° C., the polymer layer 240 is easily deformed by heat generated during a process of forming a thin film such as metal or the like. When the polymer layer 240 has a glass transition temperature of more than 250° C., the hardness of the polymer layer 240 is so high that a crack may occur or the polymer layer 240 may be separated from the mask 220 bonded to a curved portion of a mask device (not shown). Therefore, it is preferable that the polymer layer 240 has a glass transition temperature of 40 to 250° C.

Preferably, the polymer layer 240 is formed of polymer having a glass transition temperature of 100 to 200° C. As for the polymer, there are provided noncrystalline PET (polyethylene terephthalate), plasticized PVC (polyvinyl chloride), high-density PE (polyethylene), PP (polypropylene), PEI (poly-ether imide) and so on.

In this embodiment, the polymer layer 240 is provided on the mask 220 formed of metal so as to strength chemical or physical coupling with a thin film such as metal which is deposited to form a pattern on the polymer layer 240. Therefore, it is possible to prevent dust from occurring when the thin film is separated from the mask. Accordingly, a problem which may be caused by the dust can be prevented.

### Second Embodiment

Referring to FIG. 5, a shadow mask according to a second embodiment of the invention will be described. The descriptions of the same components of the second embodiment as those of the first embodiment will be omitted.

FIG. 5 is a schematic view of a shadow mask according to the second embodiment of the invention.

As shown in FIG. 5, the shadow mask 200 according to the second embodiment of the invention has almost the same construction as that of the first embodiment. The shadow mask 200 according to the second embodiment is different from the first embodiment in that a surface energy adjustment layer 300 is further formed at the interface between the mask 200 and the delamination-preventing polymer layer 240.

During a subsequent process of separating the mask 220 from the polymer layer 240, the surface energy adjustment layer 300 serves to facilitate the separation between the mask 220 and the polymer layer 240 which have a strong chemical and physical coupling force.

Preferably, the surface energy adjustment layer 300 is formed of an organic material which has a molecular weight of 5000 to 10000 g/mol.

When the surface energy adjustment layer 300 has a glass transition temperature of less than −100° C., a coupling force between the mask 200 and the polymer layer 240 which are contacted with the surface energy adjustment layer 300 cannot be maintained. Further, when the surface energy adjustment layer 300 has a glass transition temperature of more than 100° C., an adhesive force between the mask 200 and the polymer layer 240 cannot be exhibited. Therefore, it is preferable that the surface energy adjustment layer 300 has a glass transition temperature of −100 to 100° C.

More preferably, the surface energy adjustment layer 300 is formed of an organic material having a glass transition temperature of −50 to 0° C. As for the organic material, there are provided polyacrylate, polyurethane, epoxy-based oligomer and so on.

Further, to reduce surface energy such that the polymer layer 240 on which a thin film is laminated through a thin film deposition process is easily removed from the mask 220, silicon and fluorine compound may be added to the surface energy adjustment layer 300. In this case, an added amount of silicon and fluorine compound is set in the range of 1 to 20 wt %. When the amount is less than 1 wt %, the surface energy does not decrease. When the amount is more than 20 wt %, an adhesive force between the polymer layer 240 and the mask 220 becomes so weak that they may be separated from each other.

In FIG. 5, the surface energy adjustment layer 300 is illustrated as a single layer. Without being limited thereto, however, the surface energy adjustment layer 300 is composed of two or more layers.

Further, as shown in FIG. 6, an adhesive layer 400 may be provided at the interface between the surface energy adjustment layer 300 and the polymer layer 240, in order to enhance the adhesive force therebetween. FIG. 6 is a schematic view of a shadow mask according to a modification of the second embodiment of the invention.

According to the shadow mask of the present invention, as the polymer layer is formed on the mask composed of metal, the thin film formed on the mask is prevented from being delaminated, which makes it possible to prevent dust from occurring.

Further, as the surface energy adjustment layer is provided between the mask and the polymer layer, the polymer layer on which the thin film such as metal is laminated can be easily removed. Therefore, the shadow mask can be easily reused, which makes it possible to increase the lifespan of the shadow mask.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A shadow mask comprising:
a substrate;
a mask that is formed to have an opening for transferring a thin film onto the substrate in a desired shape; and
a delamination-preventing polymer layer formed on the mask.

2. The shadow mask according to claim 1, wherein the mask is formed of metal.

3. The shadow mask according to claim 1, wherein the polymer layer has a glass transition temperature of 40 to 250° C.

4. The shadow mask according to claim 1, wherein the polymer layer is composed of any one selected from the group consisting of noncrystalline PET (polyethylene terephthalate), plasticized PVC (polyvinyl chloride), high-density PE (polyethylene), PP (polypropylene), and PEI (poly-ether imide).

5. The shadow mask according to claim 1 further comprising:
a surface energy adjustment layer formed at the interface between the mask and the polymer layer.

6. The shadow mask according to claim 5, wherein the surface energy adjustment layer is composed of an organic material having a molecular weight of 5000 to 10000 g/mol.

7. The shadow mask according to claim 6, wherein the surface energy adjustment layer has a glass transition temperature of −100 to 100° C.

8. The shadow mask according to claim 6, wherein the surface energy adjustment layer is composed of any one selected from the group consisting of polyacrylate, polyurethane, and epoxy-based oligomer.

9. The shadow mask according to claim 5, wherein silicon and fluorine compound are added to the surface energy adjustment layer.

10. The shadow mask according to claim 9, wherein an added amount of the silicon and fluorine compound is set in the range of 1 to 20 wt %.

11. The shadow mask according to claim 5, wherein the surface energy adjustment layer is composed of a single layer or two or more layers.

12. The shadow mask according to claim 5 further comprising:
an adhesive layer formed at the interface between the polymer layer and the surface energy adjustment layer.
